(19) United States
(12) Patent Application Publication
(10) Pub. No.: US 2017/0003594 A1
(43) Pub. Date: Jan. 5, 2017

(54) Elastomer-Assisted Manufacturing

(71) Applicant: NORTHEASTERN UNIVERSITY, Boston, MA (US)

(72) Inventors: Sivasubramanian SOMU, Natick, MA (US); Jake RABINOWITZ, Valley Stream, NY (US)

(73) Assignee: NORTHEASTERN UNIVERSITY, Boston, MA (US)

(21) Appl. No.: 15/125,660

(22) PCT Filed: Mar. 17, 2015
(86) PCT No.: PCT/US15/21057

§ 371 Date: Sep. 13, 2016

Related U.S. Application Data
(60) Provisional application No. 61/954,234, filed on Mar. 17, 2014.

(51) Int. Cl. G03F 7/11; G03F 7/20

(52) U.S. Cl. CPC G03F 7/11; G03F 7/2059

(57) ABSTRACT

Methods of performing lithography in films attached to elastomeric substrates are provided, including methods of performing optical lithography using photoresist films on a stretched elastomeric substrate. Also described are flexible electronic devices made by the methods, and patterned substrates having small voids fabricated by the methods.

### CROSS REFERENCE TO RELATED APPLICATIONS

This application claims the benefit of Provisional Application No, 61/954,234, filed Mar. 17, 2014 and entitled “Elastomer-assisted Manufacturing”, which is hereby incorporated by reference in its entirety.

### STATEMENT REGARDING FEDERALLY SPONSORED RESEARCH OR DEVELOPMENT

The invention was developed with financial support from Grant No. 04255826 from the National Science Foundation. The U.S. Government has certain rights in the invention.

### BACKGROUND

Lithography is a method for fabricating devices on the microscale and nanoscale. Optical lithography entails spin coating a photoresist onto a substrate, exposing the photoresist to light in the visible (390 nm-700 nm) or ultraviolet (10 nm-390 nm) spectrum, and developing the photoresist in a solvent, ultimately transferring a design from a mask to a substrate. While optical lithography is both inexpensive and effective, it has a fundamental resolution limit of one-half the incident wavelength and a practical resolution limit of approximately five times the incident wavelength [1]. Much effort has been spent extending this resolution limit, with suggested solutions ranging from exploiting photon entanglement [2], to developing phase-shift masks [3,4], to immersing substrates and performing optical lithography in high-index fluids [5]. However, these modifications have their drawbacks along with the smaller resolution limits namely increased reliance upon rigid substrates.

Additional lithographic techniques exist which achieve nanoscale resolution but come with other limitations. Electron-beam lithography uses a focused, collimated electron beam rather than an optical beam, providing a standard resolution limit of 10 nm, which has been extended. down to at least 5 nm [6,7]. However, electron beam lithography remains limited by the inherent limitations of a small functional area, low speed, and high cost. Furthermore, electron beam lithography is a serial process (i.e., individual structural features must be established one after another) and thus gets exponentially slower as functional area increases, with the only current solution being to incur the extremely high cost of operating multiple electron beams in parallel. Nanoimprint lithography is an emerging technique in which a design is transferred using heat and pressure from a mold onto a resist, after which the resist is etched away to leave the mold design on the substrate [8]. Nanoimprint lithography also offers sub-10 nm resolution at low cost, but does not yet offer high yield with reliability, and is not compatible with all substrates and resists [9]. Moreover, because the printing process expels the polymer from the patterned area, there is a fundamental limit, known as the fill factor, whereby only a portion of the functional area can be patterned [10]. When the patterned area exceeds the limit, the expelled polymer will spill into other etched regions. The fill factor is a function of the mold geometry and polymer thickness and is typically around 60%. Dip-pen nanolithography involves direct deposition of organic molecules, polymers, and colloids using the tip of an atomic force microscope, doing so with high resolution and without introducing chemicals that can harm substrates [11,12]. Unfortunately, like electron beam lithography, it is a serial process and thus is quite slow and cannot cover large functional areas without incurring significant cost increases.

All the aforementioned processes were designed for rigid substrates. Flexible substrates are expected to be useful for creating electrical devices having the advantages of stretchability, flexibility, low weight, low cost, and low-κ dielectric when compared to rigid counterparts. Nevertheless, flexible and stretchable substrates have yet to realize much of their potential because of the limitations of lithographic techniques.

### SUMMARY OF THE INVENTION

The present invention provides materials and methods for use in lithographic patterning of flexible substrates and the fabrication of flexible electronic devices. The substrates include elastomeric materials, exhibiting low Young's Modulus and high deformability, as well as favorable dielectric properties. Because of these characteristics, elastomeric materials have the capacity to yield devices such as conformal photovoltaics, medical implants, sensors, and LCD and OLED displays, as well as flexible and stretchable conductors, energy storage devices, integrated micro- and macroelectronic systems, and more. The methods of the invention utilize stretching of an elastomeric substrate and lithographic patterning of the substrate in the stretched condition, followed by relaxation and deposition of conductive or non-conductive materials in the relaxed state.

Methods of performing lithography in films attached to elastomeric substrates are provided, including methods of performing lithography, such as optical or electron beam lithography, on photoresist films. Also described herein are flexible devices having small voids in films attached to elastomeric substrates, including small voids in photoresist films, which can fabricated by such methods.

One aspect of the invention is a method of performing lithography, the method including the steps of: providing an elastomeric substrate in an unstretched state, the substrate having an unstretched length lₛ in one dimension of the substrate; applying a tensile stress along the dimension of the substrate, thereby causing the substrate to stretch into a stretched state, wherein the substrate has a stretched length in the dimension of the substrate; retaining the substrate in its stretched state; optionally, depositing an adhesion-promoting layer onto the substrate; depositing a photoresist layer onto the substrate, or if present, the adhesion-promoting layer; creating a void in the photoresist layer and, if present, adhesion-promoting layer by optical lithography, the void having an initial length lᵥ along the dimension of stretching of the substrate; and relieving the tensile stress across the dimension of the substrate, whereby the substrate returns to the unstretched state, wherein the void has a final length lᵥ′ in the dimension of the substrate.

In some embodiments, the lithography is optical lithography. In some embodiments, the lithography is electron beam lithography.

In some embodiments, the step of depositing an adhesion-promoting layer onto the substrate is performed. In some embodiments, the step of depositing an adhesion-promoting layer onto the substrate is not performed. In some embodiments, the photoresist layer is deposited onto the adhesion-promoting layer. In some embodiments, the photoresist layer is deposited directly onto the substrate.

In some embodiments, the step of depositing a photoresist layer is performed in multiple steps, including a first step of depositing a photoresist sub-layer onto the substrate, or if present, the adhesion-promoting layer, and one or more additional steps of depositing a photoresist sub-layer onto a previously-deposited photoresist layer. In some embodiments, the step of a photoresist layer includes depositing a plurality of two or more photoresist sub-layers, with adjacent photoresist sub-layers optionally being separated by an adhesion-promoting sub-layer.

In some embodiments, the photoresist layer is from about 0.5 μm to about 10 μm, from about 0.5 μm to about 1 μm, from about 0.5 μm to about 2 μm, from about 0.5 μm to about 5 μm, from about 1 μm to about 2 μm, from about 1 μm to about 5 μm, from about 1 μm to about 10 μm, from about 2 μm to about 5 μm, from about 2 μm to about 10 μm, from about 5 μm to about 10 μm thick, about 0.5 μm, about 0.75 μm, about 1 μm, about 1.3 μm, about 1.5 μm, about 2 μm, about 2.5 μm, about 2.7 μm, about 3 μm, about 4 μm, about 5 μm, about 6 μm, about 7 μm, about 8 μm, about 9 μm, or about 10 μm thick.

In some embodiments, the tensile stress is applied uniformly along the dimension of the substrate. In some embodiments, the tensile stress is applied along the dimension of the substrate by an automated device. In some embodiments, tensile stress is applied along the dimension of the substrate manually.

In some embodiments, lₛ′/lₛ is from about 2 to about 10, from about 3 to about 10, from about 4 to about 10, from about 2 to about 5, from about 3 to about 5, from about 2 to about 4, about 2, about 3, about 4, about 5, about 6, about 8, or about 10. In some embodiments, lᵥ/lᵥ′ is from about 2 to about 10, from about 3 to about 10, from about 4 to about 10, from about 2 to about 5, from about 3 to about 5, from about 2 to about 4, about 2, about 3, about 4, about 5, about 6, about 8, or about 10. In some embodiments, (lᵥ/lᵥ′/(lₛ′/lₛ) is from about 1 to about 1.1, from about I to about 1.2, from about 1 to about 1.25, from about 1 to about 1.3, from about 1 to about 1.4, from about 1 to about 1.5, about 1, about 1.1, about 1.2, about 1.3, about 1.4, or about 1.5.

In some embodiments, the photoresist layer and, if present, adhesion-promoting layer are substantially free of folding, wrinkling, buckling, cracking and rupturing after relieving the tensile stress across the substrate.

In some embodiments, lᵥ′ is from about 100 nm to about 1 μm, from about 200 nm to about 1 μm, from about 400 nm to about 1 μm, from about 400 nm to about 2 μm, from about 400 nm to about 5 μm, from about 400 nm to about 10 μm, from about 400 nm to about 20 μm, from about 1 μm to about 2 μm, from about 1 μm to about 5 μm, from about 1 μm to about 10 μm, from about 1 μm to about 20 μm, less than about 1 μm, less than about 2 μm, less than about 5 μm, or less than about 10 μm.

In some embodiments, the elastomeric substrate includes a block copolymer, a cross-linked elastomer, a crosslinked polymer, a segmented copolymer, a thermoplastic elastomer, a thermoplastic epoxy, a thermoplastic polymer, a thermoplastic vulcanizate, emulsion polymerized styrene-butadiene rubber, natural rubber, polybutadiene, solution polymerized styrene-butadiene rubber, synthetic polyisoprene, synthetic rubber, or vulcanized rubber.

In some embodiments, the adhesion-promoting layer includes hexamethyldisilazane, hexamethyldisiloxane, 2-methoxy-1-methylethyl acetate, bis(trimethylsilyi)amine, 1,1,1,3,3,3,-hexamethyldisilazane, 1-methoxy-2-propanol acetate, or 2-methoxy-1-propanol acetate.

In some embodiments, the elastomeric substrate includes a material having an elastic modulus and the photoresist layer includes a material having an elastic modulus, wherein the ratio of the elastic modulus of the photoresist material to the elastic modulus of the substrate material is from about 0.75 to about 2, from about 0.75 to about 1.75, from about 0.75 to about 1.5, from about 0.75 to about 1.25, from about 0.75 to about 1, from about 01 to about 2, from about I to about 1.75, from about 1 to about 1.5, from about 1 to about 1.25, about 0.75, about 1, about 1.1, about 1.2, about 1.3, about 1.4, about 1.5, about 1.75, or about 2.

In some embodiments, the method also includes the steps of: depositing a conductive, semi-conductive, or dielectric material into the void in the photoresist layer; and removing the photoresist layer and, if present, adhesion-promoting layer from the substrate.

In another aspect, invention includes a method of performing optical lithography, the method including the steps of: providing an elastomeric substrate in an unstretched state, the substrate having an unstretched length in one dimension of the substrate and an unstretched width wₛ in another dimension orthogonal to the first dimension, wherein the two dimensions are coplanar; applying a tensile stress across the two dimensions of the substrate, thereby causing the substrate to stretch into a stretched state, wherein the substrate has a second length lₛ′ and second width wₛ′; retaining the substrate in its stretched state; optionally, depositing an adhesion-promoting layer onto the substrate; depositing a photoresist layer onto the substrate, or if present, the adhesion-promoting layer; creating a void in the photoresist layer and, if present, adhesion-promoting layer by optical lithography, the void having an initial length lᵥ along the dimension of stretching of the substrate defined by lₛ and an initial width wᵥ along the second dimension of stretching of the substrate defined by wₛ; and relieving the tensile stress across the two dimensions of the substrate, whereby the substrate returns to the unstretched state, wherein the void has a final length in the dimension of the substrate defined by lₛ and a final width wᵥ′ in the dimension of the substrate defined by wₛ.

In some embodiments, the proportion of (lₛ′/lₛ)/(wₛ′/wₛ) is about 1. In some embodiments, the proportion of (lᵥ/lᵥ′)/(wᵥ/wᵥ′) is about 1.

In another aspect, the invention includes a method of performing optical lithography, the method including the steps of: providing an elastomeric substrate in an unstretched state, the substrate having a circular area having a radius r in a plane of the substrate; applying a tensile stress radially across the plane of the substrate, thereby causing the substrate to stretch into a stretched state, wherein the circular area of the substrate has a second radius rₛ′ in the plane of the substrate; retaining the substrate in. its stretched state; optionally, depositing an adhesion-promoting layer onto the substrate; depositing a photoresist layer onto the substrate, or if present, the adhesion-promoting layer; creating a void in the photoresist layer and, if present, adhesion-promoting layer by optical lithography, the void having an initial length lᵥ along one dimension in the plane of the substrate and an initial width wᵥ along a another dimension orthogonal to the first dimension; and relieving the tensile stress across the plane of the substrate, whereby the substrate returns to the unstretched state, wherein the void has a final length lᵥ′ in the first dimension of the plane of the substrate and a final width in the second dimension of the plane of the substrate.

In another aspect, the invention includes a flexible device fabricated according to a method of the invention.

In some embodiments, the device is a conformal photovoltaic, medical implant, sensor, LCD display, OLED display, flexible and stretchable conductor, energy storage device, integrated microelectronic system, integrated or macroelectronic system.

In another aspect, the invention includes a flexible device including an elastomeric substrate, optionally, an adhesion-promoting layer attached to the elastomeric substrate, and a photoresist attached to the adhesion-promoting layer, if present, or to the elastomeric substrate, the photoresist comprising a material selected from the group consisting of PMMA, PMGI, phenol formaldehyde resin, and SU-8 and having a void with a size of less than 2 μm.

In another aspect, the invention includes a flexible device including an elastomeric substrate, optionally, an adhesion-promoting layer attached to the elastomeric substrate, and a photoresist attached to the adhesion-promoting layer, if present, or to the elastomeric substrate, the photoresist having a void with a size of less than 5 nm,

### BRIEF DESCRIPTION OF THE DRAWINGS

FIG. 1 is a schematic of an elastomer-assisted manufacturing process according to the invention. Large arrows indicate sequence of steps in the process, and small arrows indicate tensile stress forces.

FIG. 2 is a scanning electron micrograph (SEM) of metallic cross features fabricated by gold deposition and lift-off following the elastomer assisted manufacturing process. A 500 nm-thick photoresist was deposited on a elastomeric substrate manually stretched laterally to 3× its initial length. The four measured elements of the cross are indicated as x1, x2, y1, and y2 in the diagram on the left and had initial measurements of 25 μm, 125 μm, 20 μm, and 80 μm at time of patterning. Final x1, x2, y1, and y2 measurements are indicated on the SEM as Pa 1, Pa 2, Pa3, and Pa 4, respectively. Lines used to measure the x1, x2, y1, and y2 are indicated on the SEM, and angles of these lines relative to the axis of stretching are indicated as Pa 1, Pa 2, Pa3, and Pa 4, respectively. Bar represents 10 μm. Inset shows a higher magnification (2000×) of the region in the white box.

FIG. 3 is a plot of size reduction factor versus applied stretching factor for 200 μm features written in 8.1-micron thick photoresist. Substrates were automatically stretched laterally according to the indicated stretching factor prior to deposition of photoresist, cross-shaped patterns were created, and the substrate was allowed to contract. Measurements were taken when patterns were created and again after substrate was allowed to contract. The four measured elements of the cross are indicated as x1, x2, y1, and y2 in the diagram on the left and are represented in the graph as squares, circles, upward-pointing triangles, and downward-pointing triangles, respectively. Reduction factor for each element represents initial value divided by final value. Embedded in the graph are SEMs of final patterns created at each stretching factor. Magnification level of the SEMs varies.

FIG. 4A is a graph of size reduction factor versus initial dimension size of 8.1 μm thick photoresist on elastomers automatically elongated by a factor of 2× (squares), 3× (circles), 4× (upward-pointing triangles), and 5× (downward-pointing triangles). FIG. 4B is a graph of size reduction factor versus stretching factor for features with an initial dimension size of 200 μm on photoresists of thickness 0.5 μm (squares), 1.3 μm (circles), 2.7 μm (upward-pointing triangles), 5.4 μm (downward-pointing triangles), and 8.1 μm (leftward-pointing triangles).

FIG. 5A shows SEMs of various geometries patterned in photoresists while tensile stress was applied to the substrate during elastomer-assisted manufacturing. Substrates were automatically stretched laterally to 2× their original length, after whish an 8.1 μm thick photoresist was applied, patterns were created, and substrates were allowed to contract. FIG. 5B shows SEMs of the same features as in FIG. 5A after the substrate was released from tensile stress. Magnification levels of SEMs in FIGS. 5A and 5B are not the same.

FIG. 6A is an SEM of cracks and folds in a photoresist after elastomer-assisted manufacturing. Substrates were automatically stretched laterally to 4× their original length, a 8.1 μm thick photoresist was applied, patterns were created, and substrates were allowed to contract. Bar represents 10 μm. FIG. 6B is an SEM of a buckled photoresist at elastomer-photoresist interface prepared as described for FIG. 6A. Bar represents 1 μm. FIG. 6C is an SEM of a photoresist folded over an optically written feature prepared as described for FIG. 6A, with developed feature outlined. Bar represents 10 μm. FIG. 6D is an SEM of a crack from FIG. 6A at higher magnification. Bar represents 1 μm.

FIG. 7A is an optical micrograph of a photoresist that adhered to the elastomeric substrate during manufacturing. Substrates were automatically stretched laterally to 2× theft original length, a 1.3 μm thick photoresist was applied, patterns were created, and substrates were allowed to contract. FIG. 7B is an optical micrograph of a photoresist that ruptured during manufacturing. Photoresist was prepared as described for FIG. 7A. FIG. 7C is an SEM of a the photoresist shown in FIG. 7A. Bar represents 10 μm. FIG. 7D is an SEM of a the photoresist shown in FIG. 7B. Bar represents 10 μm.

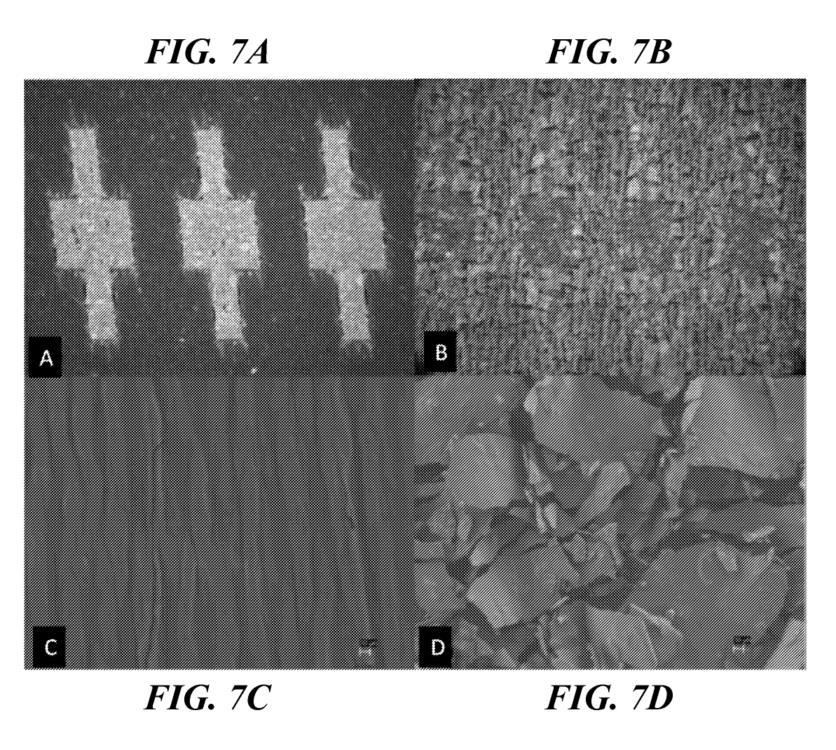

### DETAILED DESCRIPTION OF THE INVENTION

The present invention provides methods of performing lithography, including optical and electron beam lithography, in films, including photoresist films, attached to stretched elastomeric substrates. The methods of the invention entail stretching an elastomeric substrate, depositing a film on the substrate in the stretched state, creating a void in the film while the substrate is in the stretched state, and allowing the substrate to return to the unstretched state. The methods of the invention enable the creation of film voids smaller than voids that can be created by previous methods. Also described herein are flexible devices having small voids in films attached to elastomeric substrates. The methods and devices are useful in the fabrication of a variety of flexible devices.

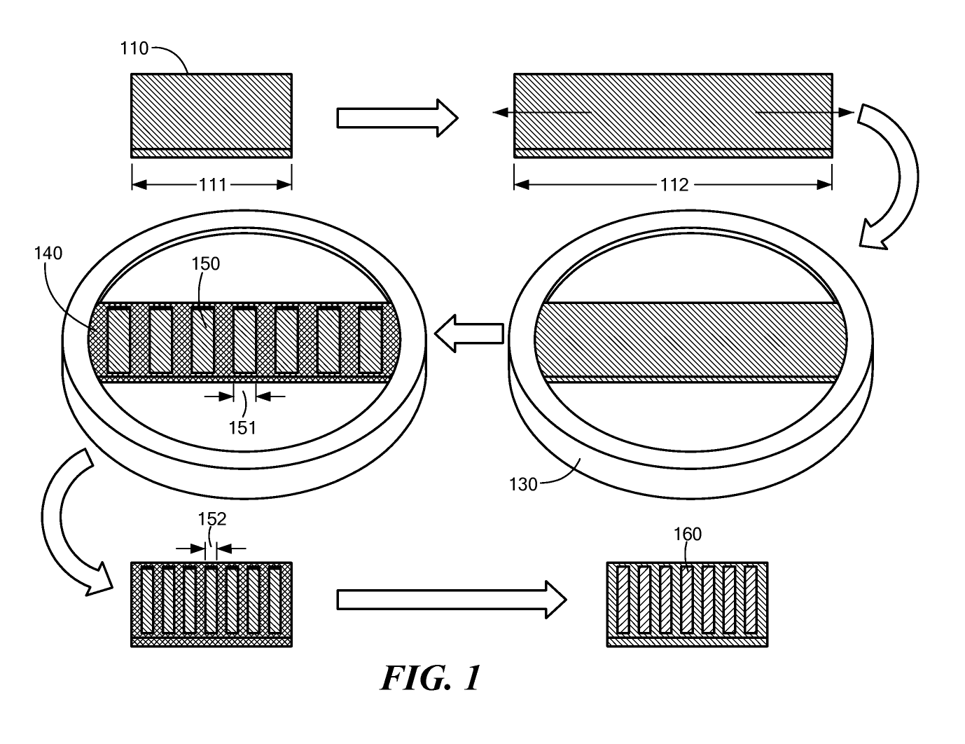

An embodiment of the method is shown in FIG. 1. In this embodiment, a substrate (110) in an unstretched state has a length lₛ (111). By applying tensile stress along one dimension of the substrate, the substrate is placed in a stretched state, in which the substrate has a longer length lₛ′ (112). The stretched substrate can be secured using a holder apparatus or a stretching apparatus (130). For example, a two-piece aluminum clamping mechanism that screws in place from the top and back sides of the substrate can be used to stabilize an applied tensile force along the axis perpendicular to the plane. Unscrewing the clamping mechanism releases the tensile strain within the system and allows the substrate to return to its initial, unstretched length. A photoresist layer (140) is applied to the substrate. The photoresist layer optionally may be attached to the substrate via an adhesion-promoting layer (not shown). If a thicker photoresist is needed, multiple adhesion-promoting layers may be applied serially. At least one void (150) having a length lᵥ (151) along the dimension of substrate stretching is created in the photoresist layer and, if present, adhesion-promoting layer by optical lithography. The void may have any shape or pattern as required for the use of the patterned substrate after deposition of filler material into the void(s) to create structural components, such as circuit components. The photoresist layer and, if present, adhesion-promoting layer may have a single void or two or more voids. If multiple voids are made, the voids may have uniform lengths and shapes or variable lengths and shapes. The structure containing the substrate, photoresist, and, if present, adhesion-promoting layer is removed from the holder, and the tensile stress is relieved. Relieve the tensile stress causes the substrate to return to the unstretched state and the length of the substrate to return to about lₛ. After release of the tensile stress, the length of the substrate may differ from lₛ by less than 1%, less than 2%, less than 3%, less than 4%, less than 5%, less than 6%, less than 7%, less than 8%, less than 9%, or less than 10%. As the substrate contracts from the stretched state to the unstretched state, the photoresist layer and, if present, adhesion-promoting layer also contract, resulting in a void length lᵥ′ (152) that is shorter than the originally-created void length.

In some embodiments, the method may be used to fabricate a flexible electronic device. As shown in FIG. 1, in such embodiments a conductive material (160) is deposited into the void(s) in the photoresist layer and, if present, adhesion-promoting layer while the substrate is in the unstretched state. The photoresist layer and, if present, adhesion-promoting layer are then removed from the substrate.

The method is compatible with any type of lithography. For example, the void may be created by optical lithography, electron beam lithography, nanoimprint lithography, or dip-pen lithography.

The resist may be made of any material that can be patterned by the chosen lithographic method and that can withstand the compression caused by contraction of the elastomeric substrate. For example, the resist can include, for example, Shipley Series S1800; Allresist products of the AR-P series and AR-N series; AZ Electronic Materials AZ photoresist series; photoresists supplied by Dow, DuPont, Electra Polymers Ltd., Eternal Chemical, Fujifilm Electronic Materials, Hitachi Chemical, HiTech Photopolymere AG, JSR Micro, Kolon Industries, MacDermid, MicroChem, Rohm and Haas, Sumitomo Chemical and Tokyo Ohka Kogyo Co., Ltd.; PMMA; PMGI; phenol formaldehyde resin; or SU-8.

In preferred embodiments, the substrate is elastomeric, such that the substrate returns to its original size and dimensions after applying and releasing the tensile stress. The substrate may be any elastomeric material. For example, the substrate may be a block copolymer, a cross-linked elastomer, a crosslinked polymer, a segmented copolymer, a thermoplastic elastomer, a thermoplastic epoxy, a thermoplastic polymer, a thermoplastic vulcanizate, emulsion polymerized styrene-butadiene rubber, natural rubber, polybutadiene, solution polymerized. styrene-butadiene rubber, synthetic polyisoprene, synthetic rubber, vulcanized rubber, polyisoprene, styrene-butadiene, polybutadiene, acrylonitrile butadiene, polydimethylsiloxane, chlorinated polyethylene rubber, chloroprene rubber, or an ethylene propylene diene monomer (M-class) rubber, or any mixture thereof. In other embodiments, the substrate may be in a plastic state, such the substrate becomes deformed during the application of tensile stress and does not return to its original dimensions. Preferably, the tensile modulus of the elastomeric material ranges from 1 to 50 MPa, and its thickness ranges from about 100 microns to several milimeters millimeters (e.g., up to about 2, 3, 4, 5, 6, 7, 8, 9, or 10 mm)

An advantage of the present method is that it can be used to make voids in resist films that are smaller than voids that can be made using, non-elastic substrates. In the method, the elastomeric substrate is stretched by a stretch factor, defined as the length of the substrate along the axis of stretching when a tensile stress is applied divided by the length of the substrate along the same axis in the absence of tensile stress. The stretching factor of the substrate can be expressed as lₛ′/lₛ. For any given embodiment of the method, the stretching factor used depends on properties of the substrate, such as its elastic modulus, thickness, temperature, etc., as well as on the mechanism used for stretching. The substrate may be stretched by any stretching factor that does not cause it to tear, break, permanently deform (i.e., transition to a plastic state), or otherwise destroy its elastomeric properties. For example, the stretching factor of the substrate may be from about 2 to about 10, from about 3 to about 10, from about 4 to about 10, from about 2 to about 5, from about 3 to about 5, from about 2 to about 4, about 2, about 3, about 4, about 5, about 6, about 8, or about 10.

A variable in the method is the reduction factor of the void in the resist film, defined as the initial length across the void along the axis of substrate stretching when the void is printed, i.e., while tensile stress is being applied to the substrate, divided by the final length across the void along the same axis, i.e., after tensile stress is released. The reduction factor of the void in the resist film can be expressed as lᵥ/lᵥ′. For any given embodiment of the method, the reduction factor depends on the critical strain limit of the resist. The strain limit is described by ε_{c}≈√(Γ/Eα), where ε_{c} is the limit, Γ is the facture energy, E is the elastic modulus, and α is the film thickness. The void in the resist may be reduced by any reduction factor that does not cause the resist to fold, wrinkle, buckle, crack, rupture, or detach from the substrate. For example, the reduction factor of the void in the resist may be from about 2 to about 10, from about 3 to about 10, from about 4 to about 10, from about 2 to about 5, from about 3 to about 5, from about 2 to about 4, about 2, about 3, about 4, about 5, about 6, about 8, or about 10.

In preferred embodiments, the reduction factor of the substrate and reduction factor of the void in the resist are about the same. For example, the ratio of the reduction factor to stretching factor, i.e., (lᵥ/lᵥ′)/(lₛ′/lₛ), may be from about 1 to about 1.1, from about 1 to about 1.2, from about 1 to about 1.25, from about 1 to about 1.3, from about 1 to about 1.4, from about 1 to about 1.5, about 1, about 1.1, about 1,2, about 1.3, about 1.4, or about 1.5. The correlation between the stretching factor of the substrate and the reduction factor of the void in the resist depends on the relative elastic moduli of the substrate and resist. Therefore, in preferred embodiments, the elastic moduli of the substrate and resist are the same or similar. For example, ratio of the elastic modulus of the resist material to the elastic modulus of the substrate material may be from about 0.75 to about 2, from about 0.75 to about 1.75, from about 0.75 to about 1.5, from about 0.75 to about 1.25, from about 0.75 to about 1, from about 01 to about 2, from about 1 to about 1.75, from about 1 to about 1.5, from about 1 to about 1.25, about 0.75, about 1, about 1.1, about 1.2, about 1.3, about 1.4, about 1.5, about 1.75, or about 2.

Another property that affects the reduction factor of the void and the adherence of the resist to the substrate is the thickness of the resist film. Thinner and thicker resist films each have advantages for use in the methods of the invention. Thinner resist films have a higher critical strain, limit and are therefore able to withstand higher degrees of stretching. Thicker resist films, however, allow for more dampening of the compressive force and therefore are better at preserving features of a void or pattern written into them. The resist film may be of any thickness suitable for use with a given substrate and method. For example, the resist film may be from about 0.5 μm to about 10 μm, from about 0.5 μm to about 1 μm, from about 0.5 μm to about 2 μm, from about 0.5 μm to about 5 μm, from about 1 μm to about 2 μm, from about 1 μm to about 5 μm, from about 1 μm to about 10 μm, from about 2 μm to about 5 μm, from about 2 μm to about 10 μm, from about 5 μm to about 10 μm thick, about 0.5 μm, about 0.75 μm, about 1 μm, about 1.3 μm, about 1.5 μm, about 2 μm, about 2.5 μm, about 2.7 μm, about 3 μm, about 4 μm, about 5 μm, about 6 μm, about 7 μm, about 8 μm, about 9 μm, or about 10 μm thick.

The mechanism of stretching the substrate also affects the structural integrity of the substrate and resist. For optimal reproducibility, the stretching mechanism should apply uniform force across the axis or dimension of stretching. Therefore, in preferred embodiments, an automated stretching mechanism is used. Alternatively, manual stretching may be used. Optimal stretching mechanisms include automated, uniform, biaxial, multiaxial, or radial stretching that yield preferably isotropic size reduction of voids in the photoresist and, if present, adhesion-promoting layer upon relaxation. Asymmetrical stress can be applied to the substrate, resulting in anisotropic or size reduction when the substrate is relaxed and consequent distortion of a feature pattern compared to the pattern established by lithography. In some embodiments of the method, the asymmetrical stress and feature distortion is taken into account, and the feature pattern or structure established by lithography is modified so that the final feature pattern or structure is the desired one. Further, the rate of stretching can be regulated and maintained sufficiently slow as to reduce or eliminate separation, buckling, folding, or distortion of a pattern established in the resist material when the stretched substrate is relaxed.

The use of an adhesion-promoting layer between the resist layer and substrate can facilitate adhesion of the resist film to the substrate as the latter is relieved of tensile stress. Therefore, the method may include application of an adhesion-promoting layer to the substrate and deposition of the resist film onto the adhesion-promoting layer. The adhesion-promoting layer may be an material that promotes adhesion of the resist to the substrate and can be patterned during the lithographic process. In some embodiments, the resist may be used as a mold for another material and subsequently removed. Consequently, it may advantageous if the adhesion-promoting layer is made of a material that can be removed along with the resist. For example, the adhesion-promoting layer may include hexamethyldisilazane, hexamethyldisiloxane, 2-methoxy-1-methylethyl acetate bis(trimethylsilyl)amine (“hexamethyldisilazane”, HMDS) 1,1,1,3,3,3,-hexamethyldisilazane, 1-methoxy-2-propanol acetate, 2-methoxy-1-propanol acetate, or mixtures thereof. Use of other adhesion-promoting layers may be advantageous, and their use and/or selection may be dictated by the interfacial chemistry of the chosen elastomeric substrate and photoresist

The method may be used to fabricate flexible devices that have conductive materials attached to an elastomeric substrate. Therefore, the method may involve the additional steps of depositing a conductive material into the void in the photoresist layer, and removing the photoresist layer and, if present, adhesion-promoting layer from the substrate. The conductive material may be, for example, aluminum, carbon nanotube based conductive composite, chromium, conductive paste, conductive polymer composite, conductive polymer, copper, germanium, gold, iron, manganese, molybdenum, nickel, silver, tungsten, or zinc. Deposition of conductive materials, non-conductive materials, semi-conductive materials, or dielectric materials can be by any known method, such as physical and chemical deposition methods.

Stretching of an elastomeric substrate in one dimension often causes compression of the substrate in the plane perpendicular to the axis of elongation. Consequently, when patterns are written onto a resist film while the substrate is in the stretched state, the features orthogonal to the axis of elongation become longer when the substrate returns to its relaxed state. The combination of contraction of features along the axis of elongation and expansion of features perpendicular to the axis of elongation causes significant distortion of two-dimensional patterns written onto a resist when the substrate is stretched in a single dimension. For some applications, however, it may be desirable to preserve to the aspect ratio of a two-dimensional pattern as the substrate transitions from stretched to unstretched state.

Proportional scaling of a pattern can be achieved by stretching the substrate simultaneously in multiple dimensions before the resist film is deposited. In some embodiments, a substantially planar substrate is stretched biaxially along two perpendicular axes (e.g., x-axis and y-axis) in the plane of the membrane. in a preferred embodiment, a two-dimensional pattern is written onto the resist such that the center of the pattern coincides with the point of intersection between the axes of elongation. In a preferred embodiment, the stretching factor is about the same in both dimensions. Alternatively, the stretching factor may differ between the two dimensions. In preferred embodiments, the stretching force is applied and. released along the two dimensions simultaneously. In other embodiments, the stretching force is applied along one dimension first and along the second dimension subsequently. In other embodiments, the stretching force is released along one dimension first and along the second dimension subsequently. Stretching in more than two dimensions also may be employed, or in two dimensions that are not perpendicular, but are offset by some angle which is not 90 degrees, but greater than or less than 90 degrees.

Alternatively, a substantially planar substrate may be stretched radially outward from a focal point. In a preferred embodiment, a two-dimensional pattern is written onto the resist such that the center of the pattern coincides with the focal point. In some embodiments, the stretching force is applied uniformly across a circle in the substrate that has the focal point as its center. In other embodiments, the stretching point is applied along a plurality of axes that all intersect at the focal point. For example, the substrate may be stretched simultaneously along 2, 3, 4, 6, 8, 10, 12 or more intersecting axes.

The invention also includes devices that include an elastomeric substrate and a resist film attached the elastomeric substrate. The resist may be attached directly to the elastomeric substrate. Alternatively, the resist may be attached to an adhesion-promoting layer that is attached to the elastomeric. substrate.

The device may be a conformal photovoltaic, medical implant, sensor, LCD display, OLED display, flexible and stretchable conductor, energy storage device, integrated microelectronic system, integrated and macroelectronic system. Alternatively, the device may be an intermediate in the fabrication of one of the aforementioned devices.

The device may have a void or gap in the resist film of less than 50 μm, less than 20 μm, less than 10 μm, less than 5 μm, less than 2 μm, less than 1 μm, less than 500 nm, less than 200 nm, less than 100 nm, less than 50 nm, less than 20 nm, less than 10 nm, less than 5 nm, less than 2 nm, less than 1 nm, less than 0.5 nm, from about 5-50 μm, about 1-10 μm, about 0.2-2 μm, about 0.1-1 μm, about 50-500 nm, about 10-100 nm, about 5-50 nm, or about 1-10 nm.

### EXAMPLES

### Example 1

### Optical Lithography on a Stretched Elastic Substrate

Extra heavy rubber latex exercise bands were purchased from Thera-Band for use as elastic substrates, Bands were stretched to desired length using an Instron tensile tester. While held in place at the desired elongated length, bands were mounted on dummy silicon wafers and held in the stretched state by customized holders. MicroChem MCC Primer 80/20 and Shipley Series S1800 photoresists were spin coated onto the elastomer at 4,000 rpm and subsequently baked on a hot plate at 180° C. for two minutes.

The maximum thickness of a photoresist layer produced by a single round of spin-coating was approximately 2.7 μm. Consequently, to generate thicker photoresist films, multiple rounds of photoresist spin-coating were performed, with substrate baking following each spin coating process. Photoresist was exposed with UV light of wavelength 365 nm and developed in Microposit MF-319 developer. The post-processed substrate was re-stretched to the elongated length using the same tensile tester, at which time the holder and dummy silicon mount were removed. The elastomer was then gradually compressed back to its initial length. In certain cases, a 100 nm thick layer of gold was deposited on the substrate through electron beam evaporation and the extant photoresist was lifted off in acetone.

### Example 2

### Analysis of Feature Distortion

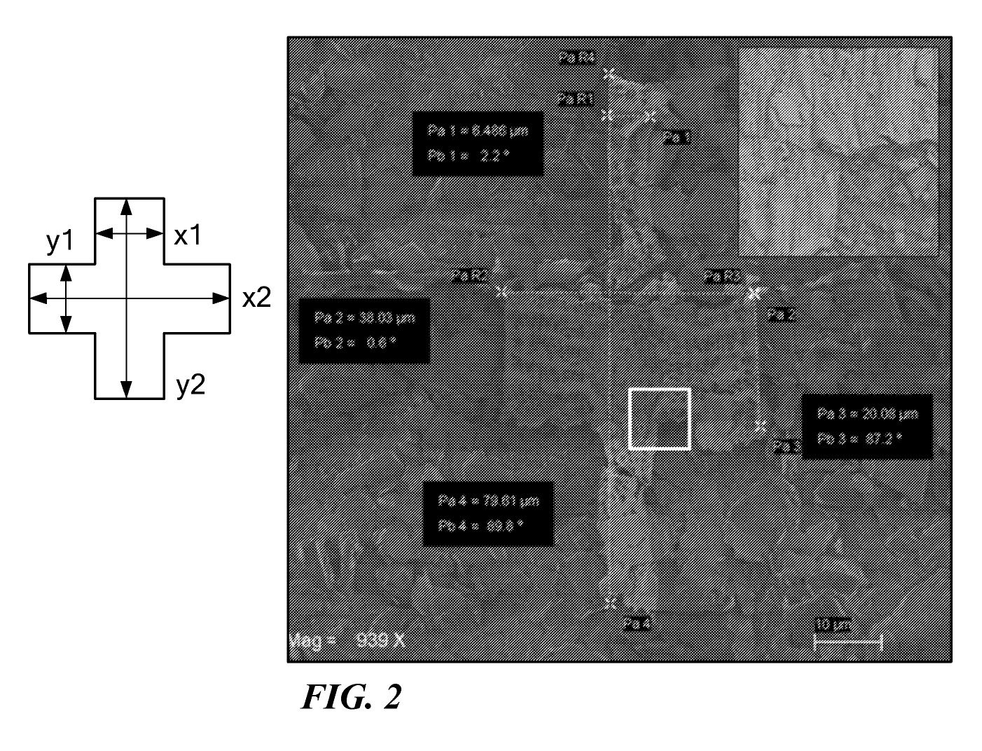

FIG. 2 shows a scanning electron micrograph (SEM) of a cross-shaped pattern created by elastomer-assisted manufacturing. A symmetric cross was patterned on a substrate manually stretched by a factor of 3×, and the substrate was allowed to return to its unstretched state. The x1 and x2 widths of the cross were initially 25 μm and 125 μm, respectively. After the substrate was returned to its unstretched state, these features were about 6.5 μm and 38 μm, respectively, a size reduction of ˜4×. In addition, each of the four measured dimensions of the cross displayed a rotation of not more than 3°, showing that the relationship between the x- and y-axes was well-preserved when the substrate contracts to its unstretched state.

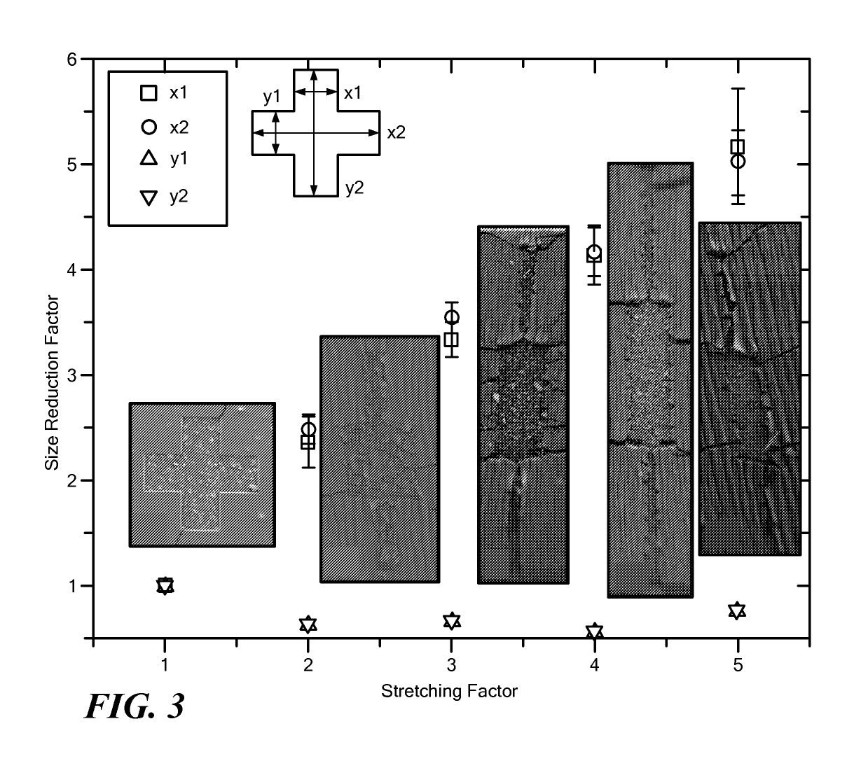

FIG. 3 depicts the linear as well as the coupled responses of optically written crosses to tensile stresses applied along the horizontal direction. The “stretching factor” is defined as the stretched elastomer length divided by the initial elastomer length; thus, an applied stretching factor of 2 corresponds to stretching the elastomer to twice its initial length before performing optical lithography. The “size reduction factor” is defined as the initial dimension length divided by the final dimension length; thus, a size reduction factor of 2 corresponds to a 200 μm feature reducing to 100 μm upon release of tensile stress. In the direction of stretching, a linear relationship was observed between the applied stretching factor and the size reduction factor, up to an applied stretching factor of 5. Error bars demonstrate that increased stretching of the elastomer introduced more variance in the size of the final pattern, a consequence that can be overcome with greater precision and process optimization.

Elastomers have relatively high Poisson's ratios, which magnified the effect of the substrate compressing in the plane perpendicular to the axis of elongation when the initial stress was applied. Upon release of the stress, the compressed plane stretched back to its original size, causing the post-processed elastomer to have “y1” and “y2” dimensions that were greater than the initial dimension size. The elongation is depicted in the figure as a size reduction factor of less than 1. The dichotomy of compression and elongation between the horizontal and vertical axes yielded the progression of crosses that are shown in the insets of FIG. 3 and became more asymmetric as the stretching factor increased. Thus, when performing one-dimensional stretching, the optically written features will always elongate in the direction perpendicular to the applied stress and the degree of elongation generally increased with greater applied stress. The molecular nature of the elastomer is the fundamental cause of the coupled elongation-compression effect. Before stretching, coiled polymers are randomly oriented in a state of maximum entropy and bound to each other by sulfur bridges [13]. When strained, the polymers begin to uncoil and align in the direction of the stress and consequently occupy less volume in the perpendicular planes. Releasing the tensile stress induces recoiling and reorientation of the molecules. As a result, a mechanized means of biaxial or radial stretching is an important and necessary progression that will allow for symmetric and isotropic feature reduction.

### Example 3

### Relationship of Feature Size Reduction to Elongation

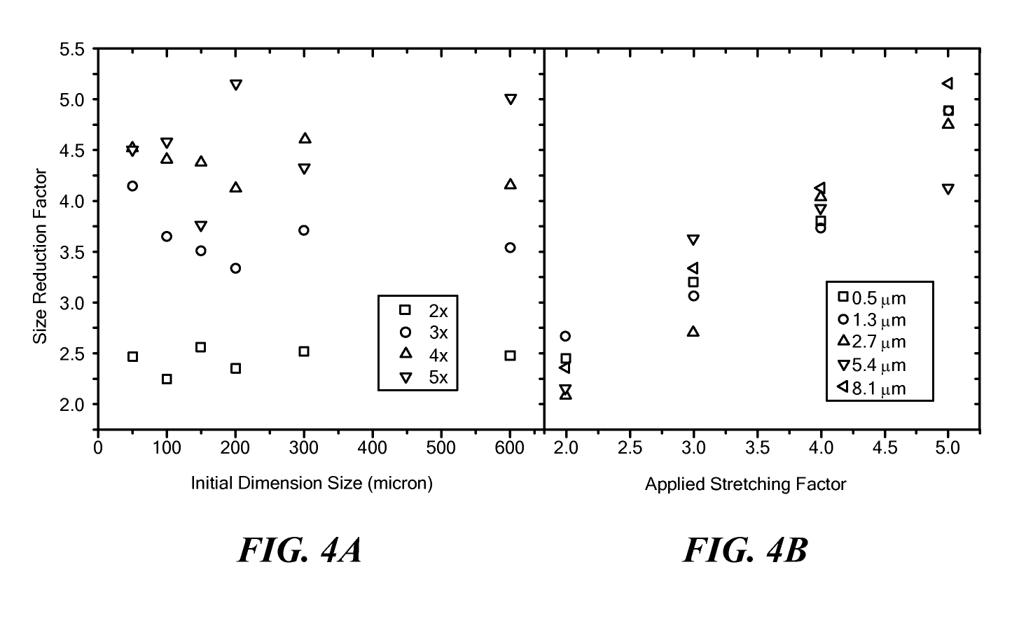

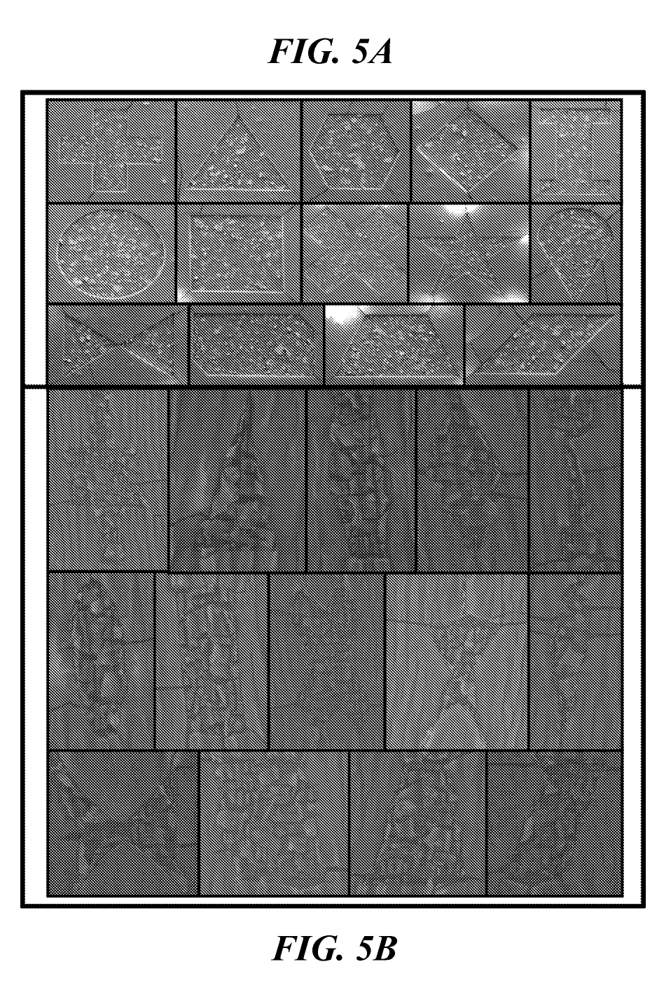

Though all results were not as tightly correlated as the data depicted in FIG. 3, the predictable relationship between feature size reduction and elastomer elongation persisted across all investigated dimension sizes and photoresist thicknesses. Described in FIG. 3, two components of the cross are measured in the direction of applied stress: “x1” and “x2”. Across all trials, “x2” was three times the length of “x1”, allowing for the range of initial dimension sizes depicted in FIG. 4A. Both dimensions of the optically written feature reduced in size during the elastomer-assisted manufacturing process, and the response to stretching was seemingly independent of initial feature size and photoresist thickness. Aside from one outlier in the 3× elongation data set, 2× elongation yielded a size reduction factor of approximately 2.4. 3× elongation yielded a factor of approximately 3.5, and 4× elongation yielded a factor of approximately 4.3. The fact that the relatively consistent size reduction lies slightly ahead of each elongation factor can be attributed to folding in the photoresist film that compressed the developed region and will be discussed in greater detail. Reproducibility and reliability became an issue when stretching the elastomer to 5× and beyond, explaining the lack of precision for the 5× data set. In addition, experimental trials investigated photoresist thicknesses ranging from 0.5-8.1 μm. Based on the random distribution of the photoresist thickness values within each cluster of data points at the experimental stretching factors, it was determined that there was no correlation between photoresist thickness and feature size reduction, though thicker films did tend to introduce more variance. Nevertheless, further optimization can mitigate the sole drawback to using the thicker photoresist films that demonstrated superior adhesion to the elastomers during processing. Shown in FIGS. 5A and 5B is a variety of shapes and how they were affected by one-dimensional stretching in the elastomer-assisted manufacturing process. The one-dimensional stretching and releasing of the elastomer yielded asymmetric patterns from symmetric ones, deforming circles into ovals, squares into rectangles, and other geometries into similarly stretched shapes.

### Example 4

### Effect of Compression on Photoresist Layer

The manufacturing process induced substantial folding, wrinkling, buckling, cracking, and rupturing of the photoresist, requiring film fracture analysis in order to fully understand the mechanisms of the system. Prior research has found that thin rigid films on elastic substrates buckle under compressive stress and crack or ruptures under tensile stress [23,24]; elastic films and carefully-compressed stiff films have been found to wrinkle sinusoidally [25,26]. Furthermore, it is known that a thin film on an elastic substrate will twist out of the plane if strong strains are induced [24] and though the elastic moduli of all the experimental photoresist are not reported in literature, the current discussion will presume them to be similar to the value of 8 GPa, reported by Calabri, et. al. [27]. The reported elastic modulus is several orders of magnitude greater than that of elastomers [13], causing slipping at the photoresist-elastomer interface and inducing buckling, wrinkling, cracks, and delamination in the photoresist when the elastomer was stretched beyond the critical strain limit of the photoresist. The strain limit is described by ε_{c}≈√(Γ/Eα) where Γ is the limit, I′ is the facture energy. E is the elastic modulus, and α is the film thickness [28]. Thus, the film will delaminate and buckle when the strain exceeds the critical limit. Because the photoresist was spin coated onto the already-stretched elastomeric substrate, the main force felt by the film was the compressive force when the elastomer shrunk back to its original size. Accordingly, releasing the tensile strain on the elastomer caused the film to buckle out of the plane, fold over itself, wrinkle, and in some cases completely lose adhesion to the substrate.

The mechanics and interactions at the photoresist-substrate interface governed many crucial elements of the system and initially hindered the effectiveness of elastomer-assisted manufacturing. Optimizing the process involved investigating whether delamination in the photoresist occurred; whether buckling was induced in the photoresist, the elastomer, or both; whether photoresist thickness affected adhesion and buckling; whether automated and gradual stretching and releasing affected adhesion and buckling; and whether an adhesion-promoting layer would dampen the recoiling force and improve photoresist-elastomer adhesion.

Experimental results were consistent with the film fracture analysis, sinusoidal film wrinkling, and the critical strain equation. The thinnest half-μm photoresist films were able to withstand higher degrees of stretching than thicker films because of the higher critical strain limit. In cases where the strain limit was exceeded, thicker films would lose all adhesion to the substrate upon being subjected to the force of the elastomer returning to its original size. However, when adhesion was maintained, thicker photoresists performed better than thinner photoresists because the greater thickness allowed for more dampening of the compressive force and protection of the optically written features. introducing adhesion-promoting layers had a similar improvement upon results. Even photoresist that maintained adhesion was found to fold upon itself, forming a periodic wrinkle geometry and locally buckle out of the plane when subjected to compressive forces.

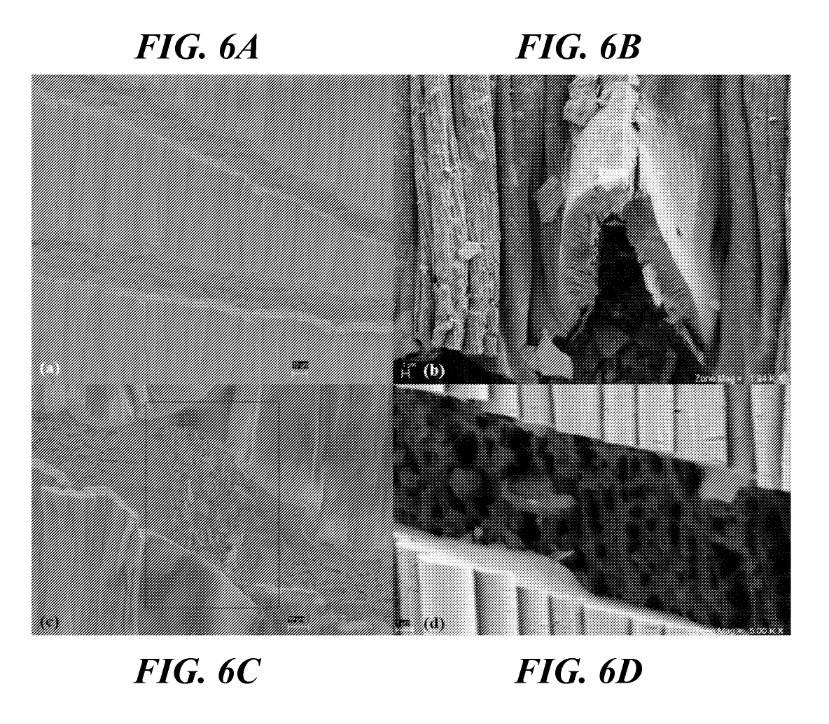

Shown in FIG. 6A is the prevalent photoresist film folding and sinusoidal wrinkling that occurred when the elastomer compressed. At the interface between the developed and undeveloped photoresist, the film consistently buckled out of the plane and folded over the elastomer, covering and concealing the optically written features (FIG. 6B). Shown in FIG. 6C, the difference in grain size clearly identifies developed photoresist, revealing a portion of the elastomer underneath the photoresist folds in the shape of the optically written feature. The photoresist experienced extensive cracking during processing as well. These cracks were again caused by the elastomer's coupled Poisson's tensor, which led to a stress on the photoresist film as the substrate elongated in the plane perpendicular to the one-dimensional stretching. As such, the fault lines typically ran across the film in the direction of the stretching and releasing cycle (FIGS. 6A and 6D). SEM imaging of the cracks identified thin strains of photoresist bridging the gap between the folded regions. When adhesion was fully degraded, the photoresist films acquired a characteristic red color and flaky texture. Shown in FIGS, 7A-7D is the clear difference, both when viewed macroscopically and when viewed under an SEM, between a photoresist film that had maintained adhesion throughout the elastomer-assisted manufacturing process and a film that had lost adhesion.

It was possible to mitigate the aforementioned effects through automated stretching and releasing of the elastomer, use of an adhesion-promoting layer, and use of thicker photoresist films. Automated and gradual stretching and releasing drastically reduced the magnitude of the forces felt by the photoresist and the substrate when manipulating the elastomer. As a result, there ceased to be complete loss of photoresist adhesion and the presence of buckling and cracking were less pronounced. Applying an adhesion-promoting layer between the elastomer and the photoresist allowed the photoresist to withstand greater tensile strain, further reduced buckling, and improved uniformity of thicker photoresist These improvements can be explained by a closer examination of how the adhesion promoter influences the photoresist-elastomer interface. By spin coating a promoter before applying photoresist, chemical adhesion was improved at the interface and the adhesive forces were able to overcome the buckling forces that were induced at high strains. Furthermore, upon releasing the tensile stress on the elastomer, the promoter layer dampened the recoil force felt by the photoresist, thereby protecting the optically written features. Without dampening the force, the features in the photoresist were susceptible to cracking and rupturing even if adhesion was maintained throughout the process. Thicker photoresists performed better than thinner films because of the same dampening effect. Once automated stretching and releasing allowed thicker films to maintain adhesion at high strains, the thicker photoresist films provided a strong damping layer to protect and yield smaller optical features than were possible with thinner photoresist films.

### REFERENCES

[1] M. J. Madou, in Fundamentals of Microfabrication: The Science of Miniaturization, CRC Press, p. 752, 2002.
[2] A. N. Boto, et al., “Quantum Interferometric Optical Lithography: Exploiting Entanglement to Beat the Diffraction Limit,” Physical Review Letters (85) no. 13, pp. 2733-6, 2000.
[3] J. A. Rogers, et al., “Using an elastomeric phase mask for sub-100 nm photolithography in the optical near field,” Applied Physical Letters (70) no. 20, pp. 2658-60, 1997.
[4] j.-W. Jang, et al., “Arrays of Nanoscale Lenses for Subwavelength Optical Lithography,” Nanoletters (10), pp. 4399-404, 2010.
[5] R. H. French, et al., “High-Index Immersion Fluids Enabling Cost-Effective Single-Exposure Lithography For 32 nm Half Pitches,” in SPIE, San Diego, 2008.
[6] C. Vieu, et al., “Electron beam lithography: resolution limits and applications,” Applied Surface Science (164), pp. 111.7, 2000.
[7] H. Duan, et al., “Sub-10-nm half-pitch electron-beam lithography by using poly(methylmethacrylate) as a negative resist,” Journal of Vacuum Science and Technology (28) no. 6, pp. 58-62, 2010.
[8] L. J. Guo, “Nanoimprint Lithography: Methods and Material Requirements,” Advanced Materials (19), pp, 495-513, 2007.
[9] C.-W. Kuo, et al., “Fabrication of Large-Area Period Nanopillar Arrays for Nanoimprint Lithography Using Polymer Colloid Masks,” Advanced Materials (15), pp. 1065-8, 2003.
[10] M.-G. Kang, et al., “Organic Solar Cells Using Nanoimprinted Transparent Metal Electrodes,” Advanced Materials (20), no. 23, pp. 4408-13, 2008.
[11] X. Liu, et al., “Arrays of Magnetic Nanopillars Patterned via ‘Dip-Pen’ Nanolithography,” Advanced Materials (14), no. 3, pp, 231-4, 2002.
[12] J.-H. Lim, et al., “Electrostatically Driven Dip-Pen Nanolithography of Conducting Polymers,” Advanced Materials (14), no. 20, pp. 1474-1477, 2002.
[13] V. L. Popov, “Viscoelastic Properties of Elastomers,” in Contact Mechanics and Friction Springer Berlin Heidelberg, pp. 231-53, 2010.
[14] S. Bauer, et al., “A Soft Future: From Robots and Sensor Skin to Energy Harvesters,” Advanced Materials (26), pp. 149-162, 2014.
[15] K. Jain, et al., “Flexible Electronics and Displays: High-Resolution, Roll-to-Roll, Projection Lithography and Photoablation Processing Technologies for High-Throughput Production,” Proceedings of the IEEE, vol. 93, no. 8, pp. 1500-10, 2005.
[16] J.-U. Meyer, et al,, “High Density Interconnects and Flexible Hybrid Assemblies for Active Biomedical Implants,” IEEE Transactions on Advanced Packaging (24), no. 3, pp. 366-74, 2001.
[17] R. II. Reuss, et al., “Macroelectronics: Perspectives on Technology and Applications,” Proceedings of the IEEE. (93), no. 7, pp. 1239-56, 2005.
[18] J. Chen, et al., “Flexible photovoltaic cells based on a graphene-CdSe quantum dot nanocomposite,” Nanoscale (4), pp, 441-3, 2012.
[19] X. Wang, et al., “Flexible Energy Storage Devices: Design Consideration and Recent Progress,” Advanced Materials (26), no. 28, pp. 4763-82, 2014.
[20] S. Yao, et al., “Nanomaterial-Enabled Stretchable Conductors: Strategies, Materials and Devices,” Advanced Materials, 2015.
[21] N. P. Cheremisinoff, Handbook of Polymer Science and Technology Volume 4: Composites and Specialty Applications, CRC Press, 1989.
[22] B. Holownia, “Effect of Poisson's Ratio on Bonded Rubber Blocks,” The Journal of Strain Analysis for Engineering Design (7), no. 3, pp. 236-42, 1972.
[23] H. Vandeparre, et al., “Localization of Folds and Cracks in Thin Metal Films Coated on Flexible Elastomer Foams,” Advanced Materials (25), no. 22, pp. 3117-3121, 2013.
[24] N. J. Douville, et al.; “Fracture of Metal Coated Elastomers,” Soft Matter (7, pp. 6493-6500, 2011.
[25] R. Huang, “Kinetic Wrinkling of an Elastic Film on a Viscoelastic Substrate.” Journal of the Mechanics and Physics of Solids (53), no, 1, pp. 63-89, 2005.
[26] J. Y. Chung, et al., “Surface Wrinkling: A Versatile Platform for Measuring Thin-Film Properties.” Advanced Materials (23), no. 3, pp. 349-68, 2011.
[27] L. Calabri, N. Pugno, A. Rota, D. Marchetto and S. Valeri, “Nanoindentation shape effects: experiments, simulations, and modeling,” Journal of Physics: Condensed Matter (19), 2007.
[28] Z. Suo, “Mechanics of stretchable electronics and soft machines,” MRS Bulletin (37), pp. 218-25, 2012.

What is claimed is:

1. A method of performing lithography, the method comprising the steps of:
(a) providing an elastomeric substrate in an unstretched state, the substrate having a first length lₛ in a dimension of the substrate;
(b) applying a tensile stress along the dimension of the substrate, thereby causing the substrate to stretch along said dimension, achieving a stretched state, wherein the substrate has a second length lₛ′ in the dimension of the substrate;
(c) retaining the substrate in its stretched state;
(d) optionally, depositing an adhesion-promoting layer onto the stretched substrate;
(e) depositing a photoresist layer onto the substrate, or if present, the adhesion-promoting layer, while the substrate is in the stretched state;
(f) creating a void in the photoresist layer and, if present, the adhesion-promoting layer by lithography, the void having a first length lᵥ along the dimension of stretch; and
(g) relieving the tensile stress, whereby the substrate returns to the unstretched state, and wherein the void has a second length lᵥ′ in said dimension.

2. The method of claim 1, wherein step (d) is performed.

3. The method of claim 1, wherein step (e) comprises depositing a plurality of two or more photoresist sub-layers, adjacent photoresist sub-layers optionally separated by an adhesion-promoting sub-layer.

4. The method of claim 1, wherein the photoresist layer is from about 0.15 μm to about 50 μm thick.

5. The method of claim 1, wherein the tensile stress is applied uniformly along the dimension of the substrate.

6. The method of claim 1, wherein the tensile stress is applied along the dimension of the substrate by an automated device.

7. The method of claim 1, wherein lₛ′/lₛ is from about 2 to about 10.

8. The method of claim 1, wherein lᵥ/lᵥ′ is from about 2 to about 10.

9. The method of claim 1, wherein (lᵥ/lᵥ′)/(lₛ′/lₛ) is from about 1 to about 1.25.

10. The method of claim 1, wherein the photoresist layer and, if present, adhesion-promoting layer are substantially free of folding, wrinkling, buckling, cracking and rupturing after relieving the tensile stress across the substrate.

11. The method of claim 1, wherein the lithography is optical lithography, and lᵥ′ is from about 400 nm to about 20 μm.

12. The method of claim 1, wherein the lithography is electron beam lithography, and lᵥ′ is from about 2 nm to about 1 μm.

13. The method of claim 1, wherein the elastomeric substrate comprises a material selected from the group consisting of a block copolymer, a cross-linked elastomer, a cross-linked polymer, a segmented copolymer, a thermoplastic elastomer, a thermoplastic epoxy, a thermoplastic polymer, a thermoplastic vulcanizate, emulsion polymerized styrene-butadiene rubber, natural rubber, polybutadiene, solution polymerized styrene-butadiene rubber, synthetic polyisoprene, synthetic rubber, and vulcanized rubber.

14. The method of claim 1, wherein a ratio of an elastic modulus of the photoresist material to an elastic modulus of the substrate material is from about 0.75 to about 2.

15. The method of claim 1, further comprising the steps of
(h) depositing a conductive, semi-conductive, or dielectric material into the void in the photoresist layer following step (g); and
(i) removing the photoresist layer and, if present, the adhesion-promoting layer from the substrate.

16. A method of performing lithography, the method comprising the steps of:
(a) providing an elastomeric substrate in an unstretched state, the substrate having a first length lₛ in a first dimension of the substrate and a first width wₛ in a second dimension orthogonal to the first dimension, wherein the first dimension and second dimension are coplanar;
(b) applying a tensile stress along the first and second dimensions of the substrate, thereby causing the substrate to stretch into a stretched state, wherein the substrate has a second length lₛ′ and second width wₛ′;
(c) retaining the substrate in its stretched state;
(d) optionally, depositing an adhesion-promoting layer onto the substrate;
(e) depositing a photoresist layer onto the substrate, or if present, the adhesion-promoting layer;
(f) creating a void in the photoresist layer and, if present, adhesion-promoting layer by lithography, the void having a first length L, along the first dimension of stretching of the substrate and a first width wᵥ along the second dimension of stretching of the substrate; and
(g) relieving the tensile stress along the first and second dimensions of the substrate, whereby the substrate returns to the unstretched state, wherein the void has a second length in the first dimension of the substrate and a second width wᵥ′ in the second dimension of the substrate.

17. The method of claim 16, wherein (lₛ′/lₛ)/(wₛ′/wₛ) is about 1.

18. The method of claim 16, wherein (lᵥ/lᵥ′)/(wᵥ/wᵥ′) is about 1.

19. A method of performing lithography, the method comprising the steps of:
(a) providing an elastomeric substrate in an unstretched state, the substrate having a circular area having a radius rₛ in a plane of the substrate;
(b) applying a tensile stress radially across the plane of the substrate, thereby causing the substrate to stretch into a stretched state, wherein the circular area of the substrate has a second radius rₛ′ in the plane of the substrate;
(c) retaining the substrate in its stretched state;
(d) optionally, depositing an adhesion-promoting layer onto the substrate;
(e) depositing a photoresist layer onto the substrate, or if present, the adhesion-promoting layer;
(f) creating a void in the photoresist layer and, if present, adhesion-promoting layer by lithography, the void having a first length lᵥ along a first dimension of the plane of the substrate and a first width w along a second dimension orthogonal to the first dimension; and
(g) relieving the tensile stress across the plane of the substrate, whereby the substrate returns to the unstretched state, wherein the void has a second length in the first dimension of the plane of the substrate and a second width wᵥ′ in the second dimension of the plane of the substrate.

20. The method of claim 19, wherein (lₛ′/lₛ)/(wₛ′/vₛ) is about 1.

21. The method of claim 19, wherein (lᵥ/lᵥ′)/(wᵥ/wᵥ′) is about 1.

22. A flexible device fabricated according to the method of claim 1.

23. The device of claim 22 wherein the device is selected from the group consisting of a conformal photovoltaic, medical implant, sensor, LCD display, OLED display, flexible and stretchable conductor, energy storage device, integrated microelectronic system, integrated and macroelectronic system.

24. A flexible device comprising:
(a) an elastomeric substrate;
(b) optionally, an adhesion-promoting layer attached to the elastomeric substrate;
(c) a photoresist attached to the adhesion-promoting layer, if present, or to the elastomeric substrate, the photoresist comprising a void with a length of less than 2 μm.

25. The device of claim 24, wherein the photoresist comprises a void with a length of less than 5 μm.
